(19) United States
(12) Patent Application Publication
(10) Pub. No.: US 2024/0421021 A1
(43) Pub. Date: Dec. 19, 2024

(54) SEMICONDUCTOR DEVICE WITH AN ACTIVE DEVICE REGION AND A CURRENT SENSOR REGION

(71) Applicant: Infineon Technologies Austria AG, Villach (AT)

(72) Inventors: Alim Karmous, Dresden (DE); Norbert Labrenz, Dresden (DE)

(21) Appl. No.: 18/676,545

(22) Filed: May 29, 2024

(30) Foreign Application Priority Data
Jun. 19, 2023 (DE) 102023205705.0

(51) Int. Cl. H01L 23/34; G01K 7/01; G01R 19/00; H01L 29/423; H01L 29/739

(52) U.S. Cl. CPC H01L 23/34; G01K 7/01; G01R 19/0092; H01L 29/4236; H01L 29/7397

(57) ABSTRACT

A semiconductor device is provided. The semiconductor device includes a substrate and an active device region having gate trenches formed at a first main surface of the semiconductor substrate. The semiconductor device further includes a current sensor region having gate trenches formed at the first main surface of the semiconductor substrate. The semiconductor device further includes a transition region arranged between the active device region and the current sensor region. The transition region includes a supplementary trench formed at the first main surface of the semiconductor substrate. The supplementary trench separates the gate trenches of the active device region from the gate trenches of the current sensor region. An electrode formed in the supplementary trench is neither electrically connected to gate electrodes formed in the gate trenches of the active device region nor electrically connected to gate electrodes formed in the gate trenches of the current sensor region.

### TECHNICAL FIELD

The present disclosure relates to a semiconductor device with an active device region and a current sensor region.

### BACKGROUND

Some power devices include current and temperature sensing mechanisms to monitor overcurrent or overtemperature operating conditions. The output of such sensing mechanisms can be passed to other control and protection circuits for controlling the operation of one or more power devices. Such control and protection circuits operate to disable power devices when an overcurrent or overtemperature operating condition is detected. The power devices should be turned off in a proper manner as early as possible to avoid a short circuit or overcurrent situation. Thus, there is a need for a reliable current and temperature sensing approach for power devices, like e. g., power semiconductor devices.

### SUMMARY

According to an example of a semiconductor device, the semiconductor device comprises a substrate and an active device region comprising a plurality of gate trenches formed at a first main surface of the semiconductor substrate. The semiconductor device further comprises a current sensor region comprising a plurality of gate trenches formed at the first main surface of the semiconductor substrate. The semiconductor device further comprises a transition region arranged between the active device region and the current sensor region. The transition region comprises a supplementary trench formed at the first main surface of the semiconductor substrate. The supplementary trench separates the plurality of gate trenches of the active device region from the plurality of gate trenches of the current sensor region. An electrode formed in the supplementary trench is neither electrically connected to gate electrodes formed in the plurality of gate trenches of the active device region nor electrically connected to gate electrodes formed in the plurality of gate trenches of the current sensor region.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements unless indicated otherwise. The elements of the drawings are not necessarily drawn to scale relative to each other. The features of the various illustrated examples can be combined unless they exclude each other.

FIG. 1A illustrates a partial top view of an exemplary semiconductor device, and FIGS. 1B-1C illustrate respective cross-sectional views of the semiconductor device;

FIGS. 2-4 illustrate partial top views of exemplary semiconductor devices;

FIG. 5 illustrates a circuit schematic of an exemplary electronic system;

FIG. 6 illustrates a top view of a layout for an exemplary semiconductor device; and

FIGS. 7A-7B and 7D-7E illustrate respective enlarged top views of exemplary semiconductor devices, and FIG. 7C illustrates a cross-sectional view of a semiconductor device.

### DETAILED DESCRIPTION

The making and using of several examples are discussed in detail below. It should be appreciated, however, that the present invention provides many applicable inventive concepts that can be embodied in a wide variety of specific contexts. The specific examples discussed are merely illustrative of specific ways to make and use the invention, and do not limit the scope of the invention.

The terms “having”, “containing”, “including”, “comprising” and the like are open, and the terms indicate the presence of stated structures, elements or features but do not preclude the presence of additional elements or features. The articles “a”, “an” and “the” are intended to include the plural as well as the singular, unless the context clearly indicates otherwise.

The terms “bonded”, “attached”, “connected” and/or “coupled” are not meant to mean that the elements or layers must directly be contacted together; intervening elements or layers may be provided between the “bonded”, “attached”, “connected” and/or “coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected” and/or “coupled” elements, respectively.

The term “electrically connected” describes a permanent low-resistive connection between electrically connected elements, for example a direct contact between the concerned elements or a low-resistive connection via a metal and/or heavily doped semiconductor material.

The terms “on” and “over” are not to be construed as meaning only “directly on” and “directly over”. Rather, if one element is positioned “on” or “over” another element (e. g., a layer is “on” or “over” another layer or “on” or “over” a substrate), a further component (e. g., a further layer) may be positioned between the two elements (e. g., a further layer may be positioned between a layer and a substrate if the layer is “on” or “over” said substrate).

Spatially relative terms, such as “beneath,” “below,” “lower,” “above,” “upper”, “under” and the like, are used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Described next, with reference to the figures, are exemplary implementations of a semiconductor device with an active device region and a current sensor region. While the exemplary implementations are described in the context of IGBT (insulated gate bipolar transistor) devices, the exemplary implementations may be realized using other types of transistors such as MOSFET (metal-oxide-semiconductor field-effect transistor) devices, BJT (bipolar junction transistor) devices, JFET (junction field-effect transistor) devices, etc. That means, references to emitter and collector may apply equally to source and drain of a MOSFET, or similar terminals of other types of transistors. In the following implementations, the first conductivity type is n-type and the second conductivity type is p-type for an n-channel device whereas the first conductivity type is p-type and the second conductivity type is n-type for a p-channel device.

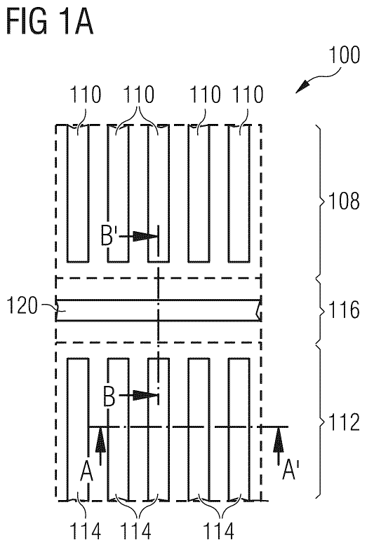

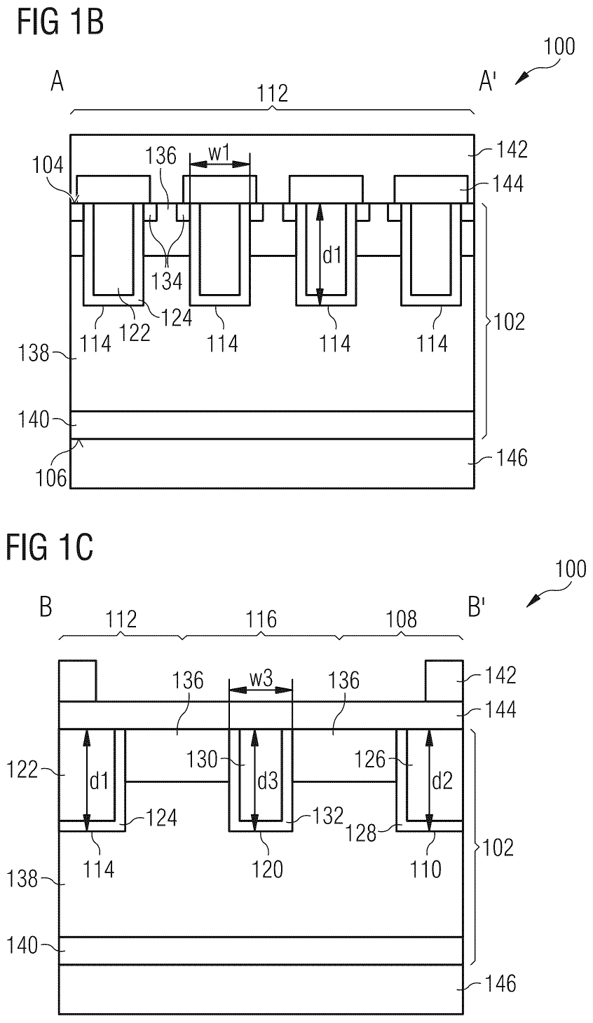

FIG. 1A illustrates a partial top view of an exemplary semiconductor device 100. FIG. 1B illustrates a cross-sectional view of the semiconductor device 100 along the line labelled A-A′ in FIG. 1A. FIG. 1C illustrates a cross-sectional view of the semiconductor device 100 along the line labelled B-B′ in FIG. 1A. It is noted that FIG. 1A contains less details than FIGS. 1B and 1C, for ease of illustration and to provide an unobstructed view.

The semiconductor device 100 includes a semiconductor substrate 102. The semiconductor substrate 102 may include one or more of a variety of semiconductor materials that are used to form semiconductor devices. For example, the semiconductor substrate 102 may include single element semiconductors (e. g. Si, Ge, etc.), silicon-on-insulator semiconductors, binary semiconductors (e. g. SiC, GaN, GaAs, SiGe, etc.), ternary semiconductors (e. g. AlGaN, InGaAs, InAlAs, etc.). The semiconductor substrate 102 may be a bulk semiconductor material or may include one or more additional elements, like e. g., epitaxial layers grown on a bulk semiconductor material, field stop regions, buffer layers, well regions, etc. The bulk semiconductor material may be referred to as base semiconductor. The semiconductor substrate 102 has a first main surface 104 and a second main surface 106 opposite the first main surface 104. The first main surface 104 may be referred to as front surface and the second main surface 106 may be referred to as back surface.

The semiconductor device 100 further includes an active device region 108 and a current sensor region 112. The active device region 108 comprises a plurality of gate trenches 110 that is formed at the first main surface 104 of the semiconductor substrate 102. The current sensor region 112 comprises a plurality of gate trenches 114 that is formed at the first main surface 104 of the semiconductor substrate 102. The semiconductor device 100 may be referred to as trench semiconductor device. The active device region 108 includes power transistor cells that form a power transistor of the semiconductor device 100 and the current sensor region 112 includes current sensor transistor cells that form a current sensor transistor of the semiconductor device 100. The power transistor may be referred to as main transistor. The current sensor cells mirror a current flowing in the active device region 108 and a current flowing through the current sensor cells can be used to sense the current flowing through the main transistor as will be described in more detail in connection with FIG. 5 below. That means, a current that is measured in the current sensor cells represents a current that flows through the active device region 108. The power transistor cells and the current sensor transistor cells may have a same configuration, pitch, etc., but with fewer current sensor transistor cells than power transistor cells, e.g., 1/10, 1/100, 1/1000 or even fewer cells as compared to the power transistor cells.

The semiconductor device 100 further includes a transition region 116 that is arranged between the active device region 108 and the current sensor region 112. The transition region 116 comprises a supplementary trench 120 that is formed at the first main surface 104 of the semiconductor substrate 102 and the supplementary trench 120 separates the plurality of gate trenches 110 of the active device region 108 from the plurality of gate trenches 114 of the current sensor region 112. In one example, the transition region 116 spatially separates the plurality of gate trenches 110 of the active device region 108 from the plurality of gate trenches 114 of the current sensor region 112 within the semiconductor substrate 102 and there is no physical connection of the plurality of gate trenches 110 of the active device region 108 with the plurality of gate trenches 114 of the current sensor region 112. The transition region 116 may be referred to as interface region and the supplementary trench 120 may be referred to as isolation trench.

As illustrated in the cross-sectional views of FIGS. 1B and 1C, the current sensor region 112 includes gate trenches 114 that are formed at the first main surface 104 of the semiconductor substrate 102 and that extend into the semiconductor substrate 102. Similarly, the active device region 108 includes gate trenches 110 that are formed at the first main surface 104 of the semiconductor substrate 102 and that extend into the semiconductor substrate 102. Gate electrodes 122 are formed in the gate trenches 114 of the current sensor region 112 and the gate electrodes 122 are separated from the semiconductor substrate 102 by a gate dielectric 124. Similarly, gate electrodes 126 are formed in the gate trenches 110 of the active device region 108 and the gate electrodes 126 are separated from the semiconductor substrate 102 by a gate dielectric 128.

An electrode 130 is formed in the supplementary trench 120 and the electrode 130 is separated from the semiconductor substrate 102 by a dielectric 132. The electrode 130 formed in the supplementary trench 120 is not electrically connected to the gate electrodes 126 formed in the gate trenches 110 of the active device region 108. In addition, the electrode 130 formed in the supplementary trench 120 is not electrically connected to the gate electrodes 122 formed in the gate trenches 114 of the current sensor region 112. That means, the electrode 130 formed in the supplementary trench 120 is neither electrically connected to the gate electrodes 126 formed in the gate trenches 110 of the active device region 108 nor electrically connected to the gate electrodes 122 formed in the gate trenches 114 of the current sensor region 112. In other words, the electrode 130 formed in the supplementary trench 120 is electrically disconnected from the gate electrodes 126 formed in the gate trenches 110 of the active device region 108 and electrically disconnected from the gate electrodes 122 formed in the gate trenches 114 of the current sensor region 112. In one example, the electrode 130 formed in the supplementary trench 120 is electrically isolated from the gate electrodes 126 formed in the gate trenches 110 of the active device region 108. In addition, the electrode 130 formed in the supplementary trench 120 is electrically isolated from the gate electrodes 122 formed in the gate trenches 114 of the current sensor region 112.

The implementation of the supplementary trench 120 and the implementation of the electrode 130 that is formed in the supplementary trench 120 and that is electrically isolated from the gate electrodes 126 of the active device region 108 as well as from the gate electrodes 122 of the current sensor region 112 allow for a reduction or suppression of a leakage current flowing from the active device region 108 to the current sensor region 112 or vice versa. In one example, the gate electrodes 126 of the active device region 108 are electrically connected to the gate electrodes 122 of the current sensor region 112. That means, the power transistor of the active device region 108 is switched on/off at the same time as the current sensor transistor of the current sensor region 112. That means, the power transistor of the active device region 108 and the current sensor transistor of the current sensor region 112 are switched on/off concurrently. In one example, the power transistor and the current sensor transistor may be switched on by applying a positive voltage to the gate electrodes 126 and to the gate electrodes 122. Further, the power transistor and the current sensor transistor may be switched off by applying a negative voltage to the gate electrodes 126 and to the gate electrodes 122. Without the presence of the electrode 130 that is formed in the supplementary trench 120 as previously described, when the power transistor and the current sensor transistor are switched off, a parasitic leakage current may flow from the active device region 108 to the current sensor region 112 or vice versa. A leakage path may occur involving body regions 136 formed at both sides of the supplementary trench 120 and a channel may be formed connecting the body regions 136 at both sides of the supplementary trench 120. The parasitic leakage current may affect negatively an operation of the semiconductor device 100 in a state where the power transistor and the current sensor transistor are switched off. For example, a measurement of a temperature of the semiconductor device 100 may be performed when the power transistor and the current sensor transistor are switched off. In the absence of the electrode 130 that is formed in the supplementary trench 120 as previously described, this temperature measurement may be distorted.

As illustrated in the cross-sectional view of FIG. 1B, the current sensor region 112 includes source regions 134 of a first conductivity type and body regions 136 of a second conductivity type that are formed between adjacent gate trenches 114. The current sensor region 112 further includes a drift region 138 of the first conductivity type and a collector region 140 of the second conductivity type. Channels form in the body regions 136 along the gate trenches 114 to provide an electrically conductive connection between the source regions 134 and the drift region 138. The channels are controlled by a voltage applied to the gate electrodes 122. It is noted that for devices that are not IGBTs, such as MOSFETs, the collector region 140 of the second conductivity type is replaced by a drain region of the first conductivity type.

A first conductive layer 142 is formed over the first main surface 104 of the semiconductor substrate 102. The first conductive layer 142 is segmented and a segment of the conductive layer 142 contacts the source regions 134 and the body regions 136. The segment is electrically isolated from the gate electrodes 122 by a segmented interlayer dielectric layer 144 that is formed over the first main surface 104 of the semiconductor substrate 102. A second conductive layer 146 is formed over the second main surface 106 of the semiconductor substrate 102 to provide a collector potential to the collector region 140. The first conductive layer 142 and/or the second conductive layer 146 may be a metallization layer.

As explained above, the current sensor cells located in the current sensor region 112 mirror the current flowing in the power transistor cells in the active device region 108 and have a similar or same cell configuration as the power transistor cells, albeit with a lower cell count. That means, the active device region 108 includes source regions of the first conductivity type, body regions of the second conductivity type, a drift region of the first conductivity type, and first and second conductive layers similar as illustrated and described for the current sensor region 112. In one example, the electrode 130 formed in the supplementary trench 120 is electrically connected to the source regions of the active device region 108. The electrode 130 is electrically isolated from the gate electrodes 126 of the active device region 108 as well as from the gate electrodes 122 of the current sensor region 112.

The current sensor cells located in the current sensor region 112 and the power transistor cells located in the active device region 108 are configured to conduct a load current between the first main surface 104 of the semiconductor substrate 102 and the second main surface 106 of the semiconductor substrate 102. The semiconductor device 100 may be referred to as vertical power semiconductor device and may be configured to conduct load currents of more than 1 A or more than 10 A or more than 30 A or hundreds of A, like e. g., in automotive applications, and may be further configured to block voltages between load terminals in the range of tens up to several thousands of volts, e. g. 10V, 400 V, 650V, 1.2 kV, 1.7 kV, 3.3 kV, 4.5 kV, 5.5 kV, 6 kV, 6.5 kV.

As illustrated in FIGS. 1B and 1C, the gate trenches 114 of the current sensor region 112 extend from the first main surface 104 of the semiconductor substrate 102 to a first depth d1 within the semiconductor substrate 102. Further, the gate trenches 114 have a first width w1. The gate trenches 110 of the active device region 108 extend from the first main surface 104 of the semiconductor substrate 102 to a second depth d2 within the semiconductor substrate 102. Further, the gate trenches 110 have a second width (not illustrated). In one example, the gate trenches 110 of the active device region 108 have at least one of a same width or a same depth as the gate trenches 114 of the current sensor region 112. Such a regular structure allows for an eased manufacturing of the semiconductor device 100 and manufacturing cost are reduced. Similarly, the supplementary trench 120 extends from the first main surface 104 of the semiconductor substrate 102 to a third depth d3 within the semiconductor substrate 102 and has a third width w3. In one example, the supplementary trench 120 has at least one of a same width or a same depth as one of the gate trenches 110 of the active device region 108 and/or one of gate trenches 114 of the current sensor region 112.

The semiconductor device 100 as illustrated and described in connection with FIGS. 1A-1C is provided as an example. Other examples may differ from what is illustrated and described with regard to FIGS. 1A-1C. For example, the shape and position of the gate trenches, the source regions, the body regions and the supplementary trench may differ from what is illustrated and described in connection with FIGS. 1A-1C. For example, contact grooves may extend from the first main surface 104 of the semiconductor substrate 102 into source regions and body regions to provide electrical contact to the source regions and body regions. Further, there may be additional conductive and interlayer dielectric layers, or fewer conductive and interlayer dielectric layers than those shown in FIGS. 1B and 1C, etc.

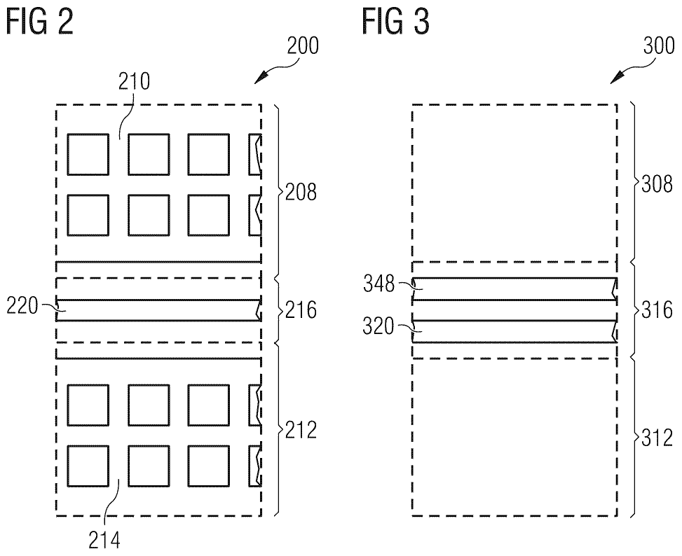

FIG. 2 illustrates a further partial top view of an exemplary semiconductor device 200. Similar to the semiconductor device 100 of FIGS. 1A-1C, the semiconductor device 200 includes an active device region 208, a current sensor region 212 and a transition region 216. The transition region 216 comprises a supplementary trench 220. The gate trenches 110, 114 of the semiconductor device 100 of FIGS. 1A-1C are stripe-shaped gate trenches that are arranged in parallel. The semiconductor device 200 of FIG. 2 differs from the semiconductor device 100 of FIGS. 1A-1C by gate trenches 210, 214 that are arranged in a grid-shape. In one example, the grid may be a rectangular, in one implementation square, or hexagonal grid. Both, the active device region 208 and the current sensor region 212 include grid-shaped gate trenches 210, 214. Source regions and body regions (not illustrated) may be arranged within the grid of gate trenches 210, 214 in a way that the source regions and body regions are surrounded by the gate trenches 210, 214.

The semiconductor devices 100, 200 as illustrated and described in connection with FIGS. 1A-1C, 2 are provided as examples. Other examples may differ from what is illustrated and described with regard to FIGS. 1A-1C, 2. For example, the gate trenches 110, 114, 210, 214 may be arranged in a way that is neither parallel nor orthogonal to each other. Further, the supplementary trenches 120, 220 may have a different shape than the stripe-shape illustrated and described in connection with FIGS. 1A-1C, 2. The trenches 110, 114, 210, 214, 120, 220 may have any type of shape, for example, an open shape such as straight stripe or, for example, a closed shape such as a grid shape.

FIG. 3 illustrates a further partial top view of an exemplary semiconductor device 300. Similar to the semiconductor devices 100, 200 of FIGS. 1A-1C, 2, the semiconductor device 300 includes an active device region 308, a current sensor region 312 and a transition region 316 comprising a supplementary trench 320. Differently, however, the transition region 316 of the semiconductor device 300 comprises a further supplementary trench 348 extending in parallel with the supplementary trench 320. Similar to an electrode that is formed in the supplementary trench 320, an electrode that is formed in the further supplementary trench 348 is electrically isolated from gate electrodes of the active device region 308 as well as from gate electrodes of the current sensor region 312. In one example, the electrode of the further supplementary trench 348 is electrically connected to source regions of the active device region 308. The electrode included in the further supplementary trench 348 may allow for an improved reduction or prevention of a leakage current flowing from the active device region 308 to the current sensor region 312 or vice versa. In one example, the further supplementary trench 348 extends at least partly in parallel with the supplementary trench 320.

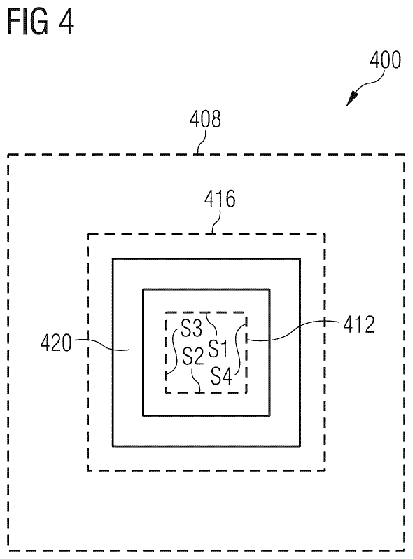

FIG. 4 illustrates a further partial top view of an exemplary semiconductor device 400. Similar to the semiconductor devices 100, 200, 300 of FIGS. 1A-1C, 2-3, the semiconductor device 400 includes an active device region 408, a current sensor region 412 and a transition region 416 comprising a supplementary trench 420. Within the semiconductor device 400, the current sensor region 412 is embedded in the active device region 408. In the example of FIG. 4, the transition region 416 and the supplementary trench 420 surround the current sensor region 412 completely to reduce or suppress a leakage current flowing from the active device region 408 to the current sensor region 412 or vice versa as explained above.

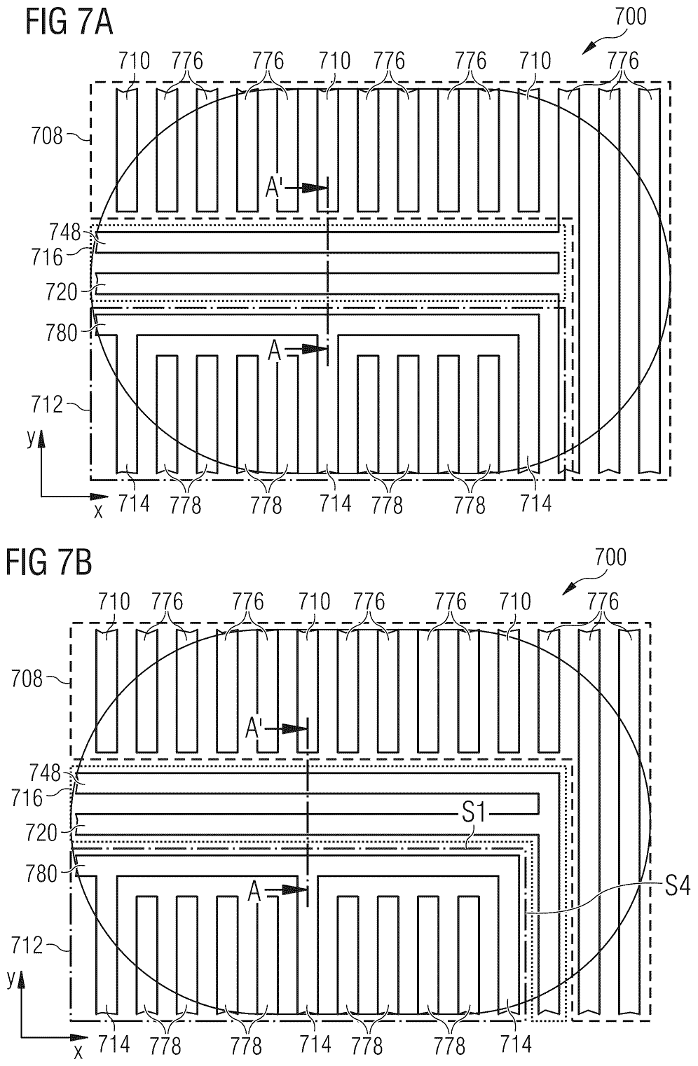

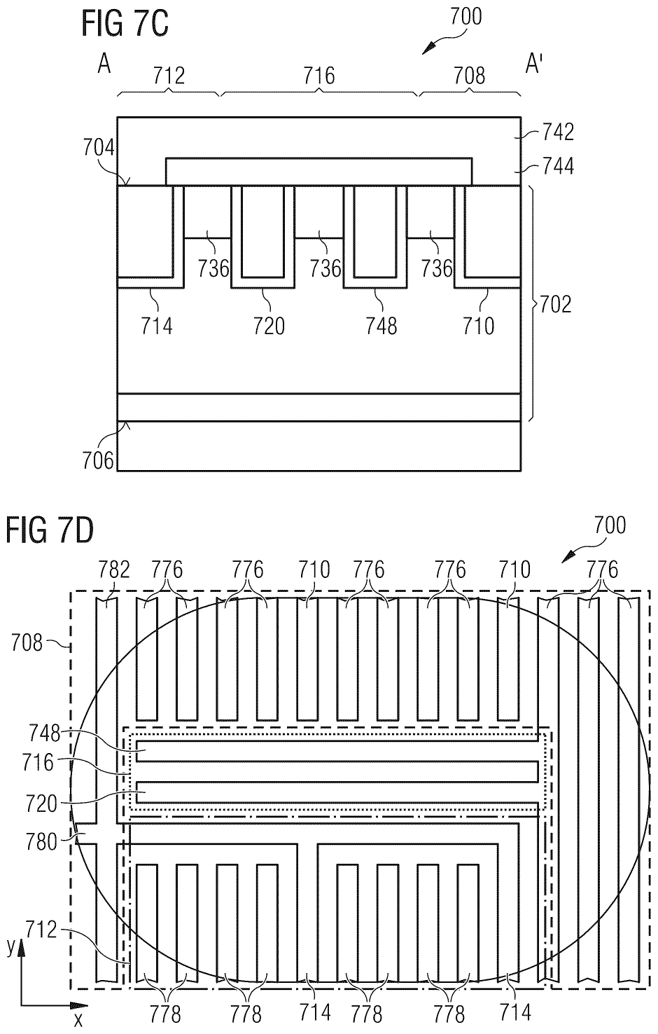

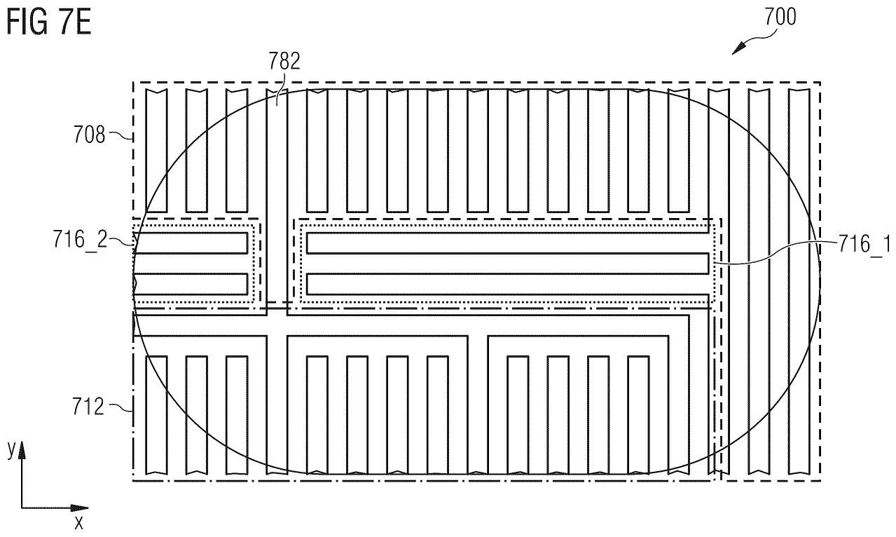

In some examples, the supplementary trench 420 may not completely surround the current sensor region 412 as illustrated in FIG. 4. Instead, the supplementary trench 420 may at least partly surround the current sensor region 412 to suppress a leakage current flowing from the active device region 408 to the current sensor region 412 or vice versa as explained above. In some examples, a supplementary trench separates a plurality of gate trenches of the active device region 408 from a plurality of gate trenches of the current sensor region 412 at a first side S1 of the current sensor region 412. In addition, a further supplementary trench separates the plurality of gate trenches of the current sensor region 412 from a plurality of further gate trenches of the active device region 408 at a second side S2 of the current sensor region 412 that is opposite to the first side S1. That means, there is no supplementary trench at either a third side S3 of the current sensor region 412 or a forth side S4 of the current sensor region 412 that is opposite to the third side S3. Besides, the supplementary trench and the further supplementary trench do not form a contiguous trench. In some examples, the number of supplementary trenches at one side may differ from the number supplementary trenches at another side. For example, as is illustrated in FIG. 7B below, at the first side S1 there may be two supplementary trenches and at the fourth side S4 there may be one supplementary trench.

FIG. 5 illustrates a circuit schematic of an exemplary electronic system 550 that is configured to sense current and temperature of a semiconductor device 500. The electronic system 550 may be part of a power electronic system such as a DC/DC converter, an AC/DC converter, a DC/AC inverter, an AC/AC converter, etc.

The semiconductor device 500 is part of the electronic system 550 and includes a main transistor 552, a current sensor transistor 554 and a temperature sensor device 556. The main transistor 552, the current sensor transistor 554 and the temperature sensor device 556 form an integrated circuit that is monolithically integrated in the semiconductor device 500. The semiconductor device 500 may be referred to as semiconductor die. A collector region of the main transistor 552 and a collector region of the current sensor transistor 554 are both electrically connected to a collector terminal 558 of the semiconductor device 500. Gate electrodes of the main transistor 552 and gate electrodes of the current sensor transistor 554 are all electrically connected to a gate terminal 560 of the semiconductor device 500. A source region of the main transistor 552 is electrically connected to an emitter terminal 562 of the semiconductor device 500 and a source region of the current sensor transistor 554 is electrically connected to a sense terminal 564 of the semiconductor device 500. The temperature sensor device 556 is electrically connected between the sense terminal 564 and the emitter terminal 562. That means, a first terminal of the temperature sensor device 556 is electrically connected to the sense terminal 564 and a second terminal of the temperature sensor device 556 is electrically connected to the emitter terminal 562.

The main transistor 552 may include an active device region that is similar or identical to an active device region 108, 208, 308, 408 explained above. The current sensor transistor 554 may include a current sensor region that is similar or identical to a current sensor region 112, 212, 312, 412 explained above. The current sensor transistor 554 mirrors a current flowing in the main transistor 552 and a current flowing through the current sensor transistor 554 can be used to sense the current flowing through the main transistor 552 as will be described in more detail below. A transition region including at least one supplementary trench is arranged between the active device region and the current sensor region as explained above. The transition region may be similar or identical to a transition region 116, 216, 316, 416 explained above and the at least one supplementary trench may be similar or identical to a supplementary trench 120, 220, 320, 348, 420 explained above.

In one example, the temperature sensor device 556 includes at least one diode that is configured to sense a temperature of the semiconductor device 500 as will be described in more detail below. An anode terminal of the at least one diode is electrically connected to the sense terminal 564 and a cathode terminal of the at least one diode is electrically connected to the emitter terminal 562. In one example, the temperature sensor device 556 includes a plurality of diodes coupled in series. The plurality of diodes coupled in series may be referred to as diode stack. In one example, an anti-parallel diode may be coupled between sense terminal 564 and the emitter terminal 562 to protect the main transistor 552 and the semiconductor device 500 from destruction in case of ESD (electrostatic discharge). Implementing diodes to sense the temperature of the semiconductor device 500 is just an example. In other examples, other semiconductor devices, like e. g., a resistor may be implemented to sense the temperature of the semiconductor device 500.

Besides the semiconductor device 500, the electronic system 550 includes further circuit elements that are configured to sense current and temperature of the semiconductor device 500. The electronic system 550 includes a switching device 566 and a current sense resistor 568 coupled in series between the sense terminal 564 and the emitter terminal 562. In one example, the switching device 566 includes a transistor. In one example, the switching device 566 may be controlled by a same signal 572 as the gate terminal 560 of the semiconductor device 500. Further, the electronic system 550 includes a current source 570 coupled between the sense terminal 564 and the emitter terminal 562. The further circuit elements that are configured to sense current and temperature of the semiconductor device 500 are provided as an example. In other examples, there may be different and/or additional circuit elements.

In a first mode of operation, the gate terminal 560 of the semiconductor device 500 and the switching device 566 are switched to a first state. In one example, the first state may be an on-state where a high or positive voltage may be applied to the gate terminal 560 and where the main transistor 552 and the current sensor transistor 554 are conducting. Further, in the first state, the switching device 566 is conducting and couples the sense terminal 564 of the semiconductor device 500 to the current sense resistor 568. In the first mode of operation, a current flowing through the current sensor transistor 554 is sensed by sensing a voltage drop across the current sense resistor 568 as measured between the sense terminal 564 and the emitter terminal 562. The voltage may be sensed at a time when the main transistor 552 and the current sensor transistor 554 are in a secure on-state. A current flowing through the main transistor 552 may be determined based on the current flowing through the current sensor transistor 554 and a ratio of a size of the main transistor 552 to a size of the current sensor transistor 554. In the first mode of operation, the semiconductor device 500 is configured to allow for a measurement of a current in the current sensor transistor 554 and the first mode of operation may be referred to as current sensing mode.

In a second mode of operation, the gate terminal 560 of the semiconductor device 500 and the switching device 566 are switched to a second state. In one example, the second state may be an off-state where a low, zero or negative voltage may be applied to the gate terminal 560 and where the main transistor 552 and the current sensor transistor 554 are non-conducting. Further, in the second state, the switching device 566 is non-conducting and decouples the sense terminal 564 of the semiconductor device 500 from the current sense resistor 568. In the second mode of operation, the current source 570 provides a constant current that flows through the temperature sensor device 556 of the semiconductor device 500. The second-state configuration allows for temperature sensing of the semiconductor device 500 by sensing a voltage drop across the temperature sensor device 556 as measured between the sense terminal 564 and the emitter terminal 562. The voltage drop may be sensed at a time when the main transistor 552 and the current sensor transistor 554 are in a secure off-state. In the second mode of operation, the semiconductor device 500 is configured to allow for a measurement of a temperature of the semiconductor device 500 and the second mode of operation may be referred to as temperature sensing mode.

In the exemplary electronic system 550 as illustrated in FIG. 5, a single terminal of the semiconductor device 500, which is the sense terminal 564, is used for both the current measurement and the temperature measurement. Thus, the sense terminal 564 may be referred to as dual mode sense terminal. Switching between current measurement and temperature measurement is effected via the signal 572. A current is measured using the sense terminal 564 when the gate terminal 560 is switched to a first state and a temperature is measured using the sense terminal 564 when the gate terminal 560 is switched to a second state.

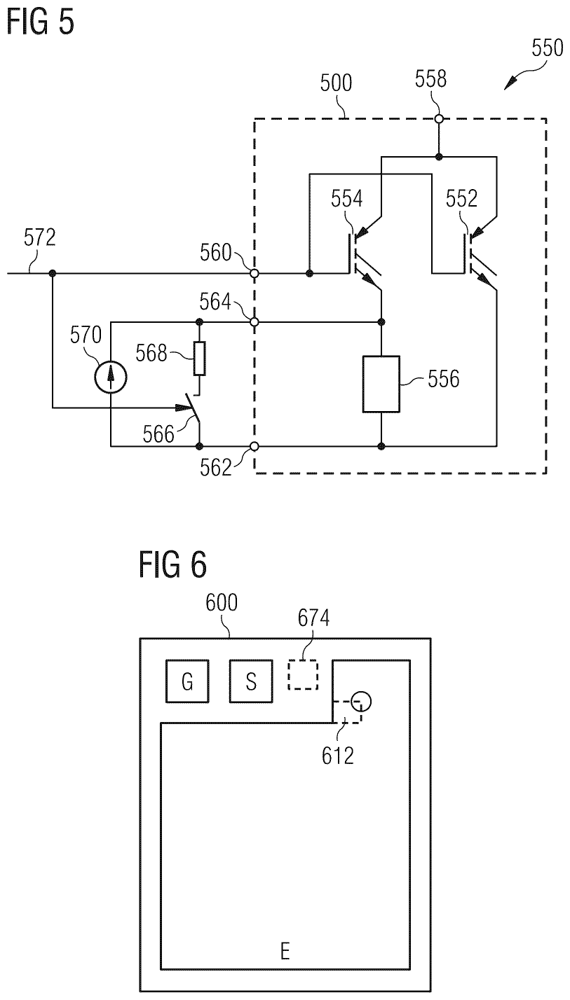

FIG. 6 illustrates a top view of a layout for an exemplary semiconductor device 600. The semiconductor device 600 may be similar or identical to the semiconductor device 500 illustrated and described in connection with FIG. 5. A gate terminal of the semiconductor device 600 is electrically connected to a gate pad G, an emitter terminal of the semiconductor device 600 is electrically connected to an emitter pad E and a sense terminal of the semiconductor device 600 is electrically connected to a sense pad S. The semiconductor device 600 is a vertical device and the gate pad G, the emitter pad E and the sense pad S are arranged over a first main surface of a substrate of the semiconductor device 600. The collector terminal is electrically connected to a collector pad that is arranged over a second main surface of the substrate that is opposite to the first main surface. Thus, the collector pad is out of view in FIG. 6.

The semiconductor device 600 includes a temperature sensor region 674 that includes semiconductor devices that form a temperature sensor device of the semiconductor device 600. The semiconductor device 600 further includes a current sensor region 612 that includes current sensor transistor cells that form a current sensor transistor of the semiconductor device 600. The semiconductor device 600 further includes an active device region that is at least partly arranged below the emitter pad E. The active device region includes power transistor cells that form a power transistor of the semiconductor device 600. A transition region including at least one supplementary trench is arranged between the active device region and the current sensor region as explained above.

The layout illustrated in FIG. 6 is just an example. In other examples, the temperature sensor region 674 may be located in positions other than those illustrated in FIG. 6. For example, the temperature sensor region 674 may be placed in or near the center of the semiconductor device 600 or the temperature sensor region 674 may be distributed over the semiconductor device 600. Similarly, the current sensor region 612, the gate pad G, the emitter pad E and/or the sense pad S may be located in positions other than those illustrated in FIG. 6. In one example, the emitter pad E may be divided into two or more emitter pads.

The sense pad S is used for both current measurement of the semiconductor device 600 and temperature measurement of the semiconductor device 600. Switching between current measurement and temperature measurement is effected via the gate pad G. Using the sense pad S for both current measurement and temperature measurement leads to minimum effort for accessing the pads, e. g. during bonding, and further, allows for high active area utilization. Besides, an electrode formed in the supplementary trench of the transition region suppresses or reduces leakage current flowing from active device region to the current sensor region or vice versa as explained above.

FIGS. 7A-7B and 7D-7E illustrate enlarged top views of a section of implementations of a semiconductor device 700 that is indicated by a circle in FIG. 6. FIG. 7C illustrates a cross-sectional view of the semiconductor device 700 along the line labelled A-A′ in FIGS. 7A-7B.

The semiconductor device 700 includes a semiconductor substrate 702. The semiconductor substrate 702 has a first main surface 704 and a second main surface 706 opposite the first main surface 704. The semiconductor device 700 further includes an active device region 708 and a current sensor region 712. The active device region 708 comprises a plurality of gate trenches 710 that is formed at the first main surface 704 of the semiconductor substrate 702 and that extends along a first direction y parallel to the first main surface 704 of the semiconductor substrate 702. The active device region 708 may be similar to an active device region 108, 208, 308, 408 explained above. Differently, the active device region 708 further comprises a plurality of emitter trenches 776 extending along the first direction y in parallel with and in between the gate trenches 710. The active device region 708 includes power transistor cells that form a power transistor of the semiconductor device 700. The emitter trenches 776 include emitter electrodes that are electrically connected to source regions that are formed in the active device region 708.

The current sensor region 712 comprises a plurality of gate trenches 714 that is formed at the first main surface 704 of the semiconductor substrate 702 and that extends along the first direction y. The current sensor region 712 may be similar to a current sensor region 112, 212, 312, 412 explained above. Differently, the current sensor region 712 further comprises a plurality of emitter trenches 778 extending along the first direction y in parallel with and in between the gate trenches 714. Further, the current sensor region 712 comprises an intersecting gate trench 780 extending at least partly along a second direction x which is orthogonal to the first direction y. The intersecting gate trench 780 connects at least a subset of the plurality of gate trenches 714 of the current sensor region 712 to each other. The current sensor region 712 includes current sensor transistor cells that form a current sensor transistor of the semiconductor device 700. The emitter trenches 778 include emitter electrodes that are electrically connected to source regions that are formed in the current sensor region 712.

The semiconductor device 700 further includes a transition region 716 that is arranged between the active device region 708 and the current sensor region 712. The transition region 716 comprises a supplementary trench 720 and a further supplementary trench 748 that are formed at the first main surface 704 of the semiconductor substrate 702. Body regions 736 are formed at both sides of the supplementary trench 120 and the further supplementary trench 748. The supplementary trench 720 and the further supplementary trench 748 separate the plurality of gate trenches 710 of the active device region 708 from the plurality of gate trenches 714 of the current sensor region 712. The transition region 716 may be similar or identical to a transition region 116, 216, 316, 416 explained above and the supplementary trench 720 and the further supplementary trench 748 may be similar or identical to a supplementary trench 120, 220, 320, 348, 420 explained above. The supplementary trench 720 and the further supplementary trench 748 extend at least partly along the second direction x and include electrodes that are not electrically connected to a plurality of gate electrodes formed in the gate trenches 710 of the active device region 708. In addition, the electrodes formed in the supplementary trench 720 and the further supplementary trench 748 are not electrically connected to a plurality of gate electrodes formed in the gate trenches 714 of the current sensor region 712. In one example, the electrodes formed in the supplementary trench 720 and the further supplementary trench 748 are electrically connected to the source regions that are formed in the active device region 708. As illustrated in FIG. 7A, the supplementary trench 720 and the further supplementary trench 748 may be connected to at least one of the plurality of emitter trenches 776 of the active device region 708. Alternatively, as illustrated in FIG. 7B, the supplementary trench 720 and the further supplementary trench 748 may not be connected to at least one of the plurality of emitter trenches 776 of the active device region 708. In the example of FIG. 7B, the electrodes formed in the supplementary trench 720 and the further supplementary trench 748 may be electrically connected to the source regions that are formed in the active device region 708 through a conductive layer formed over the semiconductor substrate 702 similar to the first conductive layer 742 illustrated in FIG. 7C. The implementation of the electrodes formed in the supplementary trench 720 and the further supplementary trench 748 allow for reduction or suppression of leakage current as previously described.

As illustrated in the cross-sectional view of FIG. 7C, a first conductive layer 742 is formed over the first main surface 704 of the semiconductor substrate 702. The first conductive layer 742 may be similar or identical to a first conductive layer 142 explained above. The plurality of gate electrodes of the active device region 708 is electrically connected to the plurality of gate electrodes of the current sensor region 712 through the conductive layer 742 formed over the semiconductor substrate 702. The first conductive layer 742 may be segmented and a segment of the conductive layer 742 may contact both the plurality of gate electrodes of the active device region 708 and the plurality of gate electrodes of the current sensor region 712. The segment of the conductive layer 742 may be electrically isolated from the electrodes formed in the supplementary trench 720 and the further supplementary trench 748 by a segmented interlayer dielectric layer 744 that is formed over the first main surface 704 of the semiconductor substrate 702. In one example, the segment of the conductive layer 742 may occupy only a part of the transition region 716 that is arranged between the active device region 708 and the current sensor region 712.

Alternatively, or additionally, as illustrated in FIG. 7D, at least one 782 of the plurality of gate trenches 710 of the active device region 708 is connected to the intersecting gate trench 780 of the current sensor region 712. Thus, the plurality of gate electrodes formed in the gate trenches 710 of the active device region 708 is electrically connected to the plurality of gate electrodes formed in the gate trenches 714 of the current sensor region 712 via the at least one 782 of the plurality of gate trenches 710 of the active device region 708. There is no supplementary trench 720 and no further supplementary trench 748 in a region where the at least one 782 of the plurality of gate trenches 710 of the active device region 708 is connected to the intersecting gate trench 780.

The semiconductor device 700 of FIG. 7E is similar to the semiconductor device 700 of FIG. 7D. Differently, however, in the semiconductor device 700 of FIG. 7D, the least one 782 of the plurality of gate trenches 710 of the active device region 708 separates the transition region 716 into a first portion 716_1 of the transition region 716 and a further portion 716_2 of the transition region 716. That means, the transition region 716 and the supplementary trenches 720, 728 are interrupted locally to allow gate signal routing.

In one example, the plurality of emitter trenches 776 of the active device region 708 has at least one of a same width or a same depth as the plurality of emitter trenches 778 of the current sensor region 712. In one example, the supplementary trench 720 and the further supplementary trench 748 have at least one of a same width or a same depth as the plurality of emitter trenches 776 of the active device region 708 or the plurality of emitter trenches 778 of the current sensor region 712. In one example, the intersecting gate trench 780 has at least one of a same width or a same depth as the plurality of gate trenches 710 of the active device region 708 or the plurality of gate trenches 714 of the current sensor region 712. With trenches having at least one of a same width or a same depth, a regular structure may be achieved and manufacturing cost of the semiconductor device 700 may be reduced.

The semiconductor device 700 illustrated in FIGS. 7A-7E is just an example. In another examples, at least a subset of the plurality of gate electrodes of the current sensor region 712 is electrically connected to each other through a conductive layer formed over the semiconductor substrate 702 similar to the first conductive layer 742 illustrated in FIG. 7C. In this example, there may be no intersecting gate trench 780 in the current sensor region 712. In one example, at least a subset of the plurality of gate electrodes of the active device region 708 is electrically connected to each other through a conductive layer similar to the first conductive layer 742 illustrated in FIG. 7C and/or through an intersecting gate trench similar to the intersecting gate trench 780 illustrated in FIG. 7A. In one example, there may be further trenches extending along the first direction y in parallel with and in between the gate trenches 710 of the active device region 708 and/or between the gate trenches 714 of the current sensor region 712. The further trenches may include electrodes that are configured to be floating. The further trenches may be referred to as dummy trenches. In one example, the transition region 716 comprises at least one supplementary trench 720.

Examples of the present invention are summarized here. Other examples can also be understood from the entirety of the specification and the claims filed herein.

Example 1: A semiconductor device comprising: a semiconductor substrate; an active device region comprising a plurality of gate trenches formed at a first main surface of the semiconductor substrate; a current sensor region comprising a plurality of gate trenches formed at the first main surface of the semiconductor substrate; and a transition region arranged between the active device region and the current sensor region, wherein the transition region comprises a supplementary trench formed at the first main surface of the semiconductor substrate and wherein the supplementary trench separates the plurality of gate trenches of the active device region from the plurality of gate trenches of the current sensor region, and wherein an electrode formed in the supplementary trench is neither electrically connected to gate electrodes formed in the plurality of gate trenches of the active device region nor electrically connected to gate electrodes formed in the plurality of gate trenches of the current sensor region.

Example 2: The semiconductor device of example 1, further comprising: an emitter/source pad formed over the semiconductor substrate and electrically connected to a source region formed in the active device region; a sense pad formed over the semiconductor substrate and electrically connected to a source region formed in the current sensor region; and a gate pad formed over the semiconductor substrate and electrically connected to the plurality of gate electrodes of the active device region and to the plurality of gate electrodes of the current sensor region.

Example 3: The semiconductor device of example 2, wherein the electrode formed in the supplementary trench is electrically connected to the source region of the active device region.

Example 4: The semiconductor device of any of examples 2 or 3, further comprising: a temperature sensor region comprising a temperature sensor device, wherein a first terminal of the temperature sensor device is electrically connected to the sense pad.

Example 5: The semiconductor device of example 4, wherein the semiconductor device is configured to allow for a measurement of a current in the current sensor region using the sense pad when the gate pad is switched to a first state, and wherein the semiconductor device is further configured to allow for a measurement of a temperature of the semiconductor device using the sense pad when the gate pad is switched to a second state.

Example 6: The semiconductor device of example 5, wherein the first state is an on-state and the second state is an off-state.

Example 7: The semiconductor device of any of examples 4 to 6, wherein a second terminal of the temperature sensor device is electrically connected to the emitter/source pad.

Example 8: The semiconductor device of any of examples 4 to 7, wherein the temperature sensor device comprises a plurality of diodes coupled in series.

Example 9: The semiconductor device of any of the preceding examples, further comprising: a further supplementary trench extending in parallel with the supplementary trench.

Example 10: The semiconductor device of any of the preceding examples, wherein the supplementary trench at least partly surrounds the current sensor region.

Example 11: The semiconductor device of any of the preceding examples, wherein the current sensor region is embedded in the active device region, the supplementary trench separates the plurality of gate trenches of the active device region from the plurality of gate trenches of the current sensor region at a first side of the current sensor region and a further supplementary trench separates the plurality of gate trenches of the current sensor region from a plurality of further gate trenches of the active device region at a second side of the current sensor region that is opposite to the first side.

Example 12: The semiconductor device of any of the preceding examples, wherein the plurality of gate trenches of the active device region has at least one of a same width or a same depth as the plurality of gate trenches of the current sensor region.

Example 13: The semiconductor device of any of the preceding examples, wherein the plurality of gate trenches of the active device region extends along a first direction parallel to the first main surface of the semiconductor substrate, the active device region further comprises a plurality of emitter trenches extending along the first direction in parallel with and in between the gate trenches, the plurality of gate trenches of the current sensor region extends along the first direction parallel to the first main surface of the semiconductor substrate, the current sensor region further comprises a plurality of emitter trenches extending along the first direction in parallel with and in between the gate trenches, and the supplementary trench extends at least partly along a second direction which is orthogonal to the first direction.

Example 14: The semiconductor device of example 13, wherein the plurality of emitter trenches of the active device region has at least one of a same width or a same depth as the plurality of emitter trenches of the current sensor region.

Example 15: The semiconductor device of any of examples 13 or 14, wherein the supplementary trench has at least one of a same width or a same depth as the plurality of emitter trenches of the active device region or the plurality of emitter trenches of the current sensor region.

Example 16: The semiconductor device of any of examples 13 to 15, further comprising an intersecting gate trench extending at least partly along the second direction and connecting at least a subset of the plurality of gate trenches of the current sensor region to each other.

Example 17: The semiconductor device of example 16, wherein the intersecting gate trench has at least one of a same width or a same depth as the plurality of gate trenches of the active device region or the plurality of gate trenches of the current sensor region.

Example 18: The semiconductor device of any of examples 16 or 17, wherein at least one of the plurality of gate trenches of the active device region is connected to the intersecting gate trench.

Example 19: The semiconductor device of any of examples 16 or 17, wherein the plurality of gate electrodes of the active device region is electrically connected to the plurality of gate electrodes of the current sensor region through a conductive layer formed over the semiconductor substrate.

Example 20: The semiconductor device of any of examples 13 to 15, wherein at least a subset of the plurality of gate electrodes of the current sensor region is electrically connected to each other through a conductive layer formed over the semiconductor substrate.

While this invention has been described with reference to illustrative examples, this description is not intended to be construed in a limiting sense. Various modifications and combinations of the illustrative examples, as well as other examples of the invention, will be apparent to persons skilled in the art upon reference to the description. It is therefore intended that the appended claims encompass any such modifications or examples.

What is claimed is:

1. A semiconductor device, comprising:
a semiconductor substrate;
an active device region comprising a plurality of gate trenches formed at a first main surface of the semiconductor substrate;
a current sensor region comprising a plurality of gate trenches formed at the first main surface of the semiconductor substrate; and
a transition region arranged between the active device region and the current sensor region,
wherein the transition region comprises a supplementary trench formed at the first main surface of the semiconductor substrate,
wherein the supplementary trench separates the plurality of gate trenches of the active device region from the plurality of gate trenches of the current sensor region,
wherein an electrode formed in the supplementary trench is neither electrically connected to gate electrodes formed in the plurality of gate trenches of the active device region nor electrically connected to gate electrodes formed in the plurality of gate trenches of the current sensor region.

2. The semiconductor device of claim 1, further comprising:
an emitter/source pad formed over the semiconductor substrate and electrically connected to a source region formed in the active device region;
a sense pad formed over the semiconductor substrate and electrically connected to a source region formed in the current sensor region; and
a gate pad formed over the semiconductor substrate and electrically connected to the gate electrodes of the active device region and to the gate electrodes of the current sensor region.

3. The semiconductor device of claim 2, wherein the electrode formed in the supplementary trench is electrically connected to the source region of the active device region.

4. The semiconductor device of claim 2, further comprising:
a temperature sensor region comprising a temperature sensor device,
wherein a first terminal of the temperature sensor device is electrically connected to the sense pad.

5. The semiconductor device of claim 4, wherein the semiconductor device is configured to allow for a measurement of a current in the current sensor region using the sense pad when the gate pad is switched to a first state, and wherein the semiconductor device is further configured to allow for a measurement of a temperature of the semiconductor device using the sense pad when the gate pad is switched to a second state.

6. The semiconductor device of claim 5, wherein the first state is an on-state and the second state is an off-state.

7. The semiconductor device of claim 4, wherein a second terminal of the temperature sensor device is electrically connected to the emitter/source pad.

8. The semiconductor device of claim 4, wherein the temperature sensor device comprises a plurality of diodes coupled in series.

9. The semiconductor device of claim 1, further comprising:
a further supplementary trench extending in parallel with the supplementary trench.

10. The semiconductor device of claim 1, wherein the supplementary trench at least partly surrounds the current sensor region.

11. The semiconductor device of claim 1, wherein:
the current sensor region is embedded in the active device region;
the supplementary trench separates the plurality of gate trenches of the active device region from the plurality of gate trenches of the current sensor region at a first side of the current sensor region; and
a further supplementary trench separates the plurality of gate trenches of the current sensor region from a plurality of further gate trenches of the active device region at a second side of the current sensor region that is opposite to the first side.

12. The semiconductor device of claim 1, wherein the plurality of gate trenches of the active device region has at least one of a same width or a same depth as the plurality of gate trenches of the current sensor region.

13. The semiconductor device of claim 1, wherein:
the plurality of gate trenches of the active device region extends along a first direction parallel to the first main surface of the semiconductor substrate;
the active device region further comprises a plurality of emitter trenches extending along the first direction in parallel with and in between the gate trenches;
the plurality of gate trenches of the current sensor region extends along the first direction parallel to the first main surface of the semiconductor substrate;
the current sensor region further comprises a plurality of emitter trenches extending along the first direction in parallel with and in between the gate trenches; and
the supplementary trench extends at least partly along a second direction which is orthogonal to the first direction.

14. The semiconductor device of claim 13, wherein the plurality of emitter trenches of the active device region has at least one of a same width or a same depth as the plurality of emitter trenches of the current sensor region.

15. The semiconductor device of claim 13, wherein the supplementary trench has at least one of a same width or a same depth as the plurality of emitter trenches of the active device region or the plurality of emitter trenches of the current sensor region.

16. The semiconductor device of claim 13, further comprising:
an intersecting gate trench extending at least partly along the second direction and connecting at least a subset of the plurality of gate trenches of the current sensor region to each other.

17. The semiconductor device of claim 16, wherein the intersecting gate trench has at least one of a same width or a same depth as the plurality of gate trenches of the active device region or the plurality of gate trenches of the current sensor region.

18. The semiconductor device of claim 16, wherein at least one of the plurality of gate trenches of the active device region is connected to the intersecting gate trench.

19. The semiconductor device of claim 16, wherein the gate electrodes of the active device region are electrically connected to the gate electrodes of the current sensor region through a conductive layer formed over the semiconductor substrate.

20. The semiconductor device of claim 13, wherein at least a subset of the gate electrodes of the current sensor region is electrically connected to each other through a conductive layer formed over the semiconductor substrate.
